(19) United States
(12) Patent Application Publication
(10) Pub. No.: US 2025/0126763 A1
(43) Pub. Date: Apr. 17, 2025

(54) HEAT DISSIPATION STRUCTURE, DISPLAY MODULE, ELECTRONIC DEVICE, AND PROCESSING METHOD FOR DISPLAY MODULE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Jiaxiang Wang, Beijing (CN); Binfeng Feng, Beijing (CN); Zijie Zhang, Beijing (CN); Fei Li, Beijing (CN); Qi Huang, Beijing (CN); Shangnan Jin, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/567,461

(22) PCT Filed: May 23, 2023
(86) PCT No.: PCT/CN2023/095701

§ 371 Date: Dec. 6, 2023

(30) Foreign Application Priority Data
May 23, 2022 (CN) 202210564704.6

(51) Int. Cl. H05K 7/20

(52) U.S. Cl. CPC H05K 7/20963

(57) ABSTRACT

This disclosure relates to a heat dissipation structure, a display module, an electronic device, and a processing method for a display module. The heat dissipation structure includes: a first heat dissipation layer, a support layer and a second heat dissipation layer. The support layer and the second heat dissipation layer are disposed on a same side of the first heat dissipation layer, and an orthographic projection of the support layer onto the first heat dissipation layer and an orthographic projection of the second heat dissipation layer onto the first heat dissipation layer do not overlap.

### CROSS-REFERENCE TO RELATED APPLICATIONS

This application claims priority to Chinese Patent Application No. 202210564704.6 filed in China on May 23, 2022, disclosure of which is hereby incorporated by reference.

### TECHNICAL FIELD

The present disclosure relates to the technical field of display modules, and more particularly, to a heat dissipation structure, a display module, an electronic device, and a processing method for a display module.

### BACKGROUND

With more and more requirements on user experience of vehicle display, vehicle displays become more and more diversified. It is proposed to use a double-sided curved edge (Edge) form for the design of the console screen. Currently, there are mobile phone designs having an OLED screen of the Edge form. Because edges of the glass cover plate is pasted to a middle frame during the assembly of the middle frame, a display screen pasted with a flexible heat dissipation structure (SCF) on the back side can meet the requirements.

In the vehicle-mounted display products, because of a large size, heavy weight of the screen and usage scenario limitations, in order to meet the requirements on vehicle-mounted products, such as the strength requirement, heat dissipation requirement, particularly the installation requirement, the supporting plate (aluminum plate, titanium alloy, etc.) behind the display screen is required for assembly into the complete product. Due to the aforementioned requirements on strength, heat dissipation and installation, conventional heat dissipation structures for vehicle-mounted display present significant challenges for subsequent usage.

### SUMMARY

The present disclosure provides a heat dissipation structure, a display module, an electronic device, and a processing method for a display module, for solving the problem of uneven heat dissipation of the heat dissipation structure in the related art.

In order to solve the above-mentioned problems, the present disclosure provides a heat dissipation structure, including: a first heat dissipation layer, a support layer and a second heat dissipation layer. The support layer and the second heat dissipation layer are disposed on a same side of the first heat dissipation layer, and an orthographic projection of the support layer onto the first heat dissipation layer and an orthographic projection of the second heat dissipation layer onto the first heat dissipation layer do not overlap.

Optionally, the support layer and the second heat dissipation layer have a gap therebetween, wherein the gap is between 0.1 mm and 0.45 mm.

Optionally, a thickness of the support layer is the same as a thickness of the second heat dissipation layer.

Optionally, the second heat dissipation layer includes a plurality of heat dissipation sub-layers, and the heat dissipation sub-layers are arranged in a stack.

Optionally, the heat dissipation sub-layers are made of a same material, or the plurality of heat dissipation sub-layers are made of different materials.

Optionally, the first heat dissipation layer includes a copper foil layer and a meshed adhesive layer, the second heat dissipation layer and the support layer are arranged on a same side of the copper foil layer, and the meshed adhesive layer is located on a side of the copper foil layer facing away from the support layer.

Optionally, the first heat dissipation layer further includes a foam layer, and the foam layer is located between the copper foil layer and the meshed adhesive layer.

According to another aspect of the present disclosure, a display module is provided, the display module includes: the above-mentioned heat dissipation structure; and a display panel, including a first region and a second region connected to each other, wherein the second region is deformable by bending, the heat dissipation structure is attached to the display panel, the first heat dissipation layer is located in the first region and the second region, the support layer is located in the first region, and the second heat dissipation layer is located in the second region.

Optionally, a side of the heat dissipation structure facing away from the support structure is flush with a side of the second region facing away from the first region in a plane perpendicular to the display module; or a side edge of the heat dissipation structure facing away from the support structure is closer to the support structure than a side edge of the second region facing away from the first region.

Optionally, the second heat dissipation layer has a predetermined distance from a bending start point of the second region.

According to another aspect of the present disclosure, an electronic device is provided. The electronic device includes a display module, the display module being the above-described display module.

According to another aspect of the present disclosure, there is also provided a processing method for a display module, the display module being the above-mentioned display module, the processing method including the following steps: providing a heat dissipation structure in a second region of the display panel; attaching a bearing film on a side of the heat dissipation structure facing away from the display panel; and bending the display panel having the heat dissipation structure by applying a force to the bearing film.

Optionally, the method further includes: after bending the display panel having the heat dissipation structure, attaching the bent display panel having the heat dissipation structure onto a flexible printed circuit board.

The above-mentioned technical solutions provided by the embodiments of the present disclosure have the following advantages compared with the related art.

With the technical solution of the present disclosure, heat dissipation are generally effected through three modes: heat radiation, heat conduction and heat convection. A support layer and a second heat dissipation layer are provided on the same side of the first heat dissipation layer, so that heat dissipation tends to be consistent in the region where the support layer is provided and the region where the second heat dissipation layer is provided, and a large temperature difference between the region of the first heat dissipation layer where the support layer is located and the region of the first heat dissipation layer where the second heat dissipation layer is located is avoided. In addition, the orthographic projection of the support layer onto the first heat dissipation layer and the orthographic projection of the second heat dissipation layer onto the first heat dissipation layer do not overlap, such that the support layer and the second heat dissipation layer are less likely to interfere with each other when the heat dissipation structure is bent. The technical solution of the present disclosure effectively solves the problem of uneven heat dissipation of the heat dissipation structure in the related art.

### BRIEF DESCRIPTION OF THE DRAWINGS

The accompanying drawings, which are incorporated in and constitute a part of this specification, illustrate embodiments consistent with the disclosure and, together with the description, serve to explain the principles of the disclosure.

In order to explain the embodiments of the present disclosure or the technical solutions in the related art more clearly, the following simple description of the accompanying drawings which are used in the embodiments or the description of the related art will be given; it would be obvious for a person skilled in the art that other drawings can be obtained according to these drawings without involving any creative effort.

FIG. 1 is a schematic view showing the structure of a display module according to a first embodiment in a flat state;

FIG. 2 is a schematic view showing the structure of a second region of the display module according to the first embodiment in a bent state;

FIG. 3 is a schematic view showing the structure of a second region of a display panel of the display module of FIG. 2 in the bent state;

FIG. 4 is a schematic view showing the structure of a display module according to a second embodiment in a flat state;

FIG. 5 is a schematic view showing the structure of a display module according to a third embodiment in a flat state;

FIG. 6 is a schematic view showing the structure of a display module according to a fourth embodiment in a flat state;

FIG. 7 is a schematic view showing a portion of structures of an electronic device of the present disclosure;

FIG. 8 is a schematic view showing the structure of the electronic device of FIG. 4 in another perspective.

The above-mentioned figures include the following reference signs:
10, first heat dissipation layer; 11, copper foil layer; 12, meshed adhesive layer; 13, foam layer; 20, support layer; 30, second heat dissipation layer; 31, heat dissipation sub-layer; 40, display panel; 41, first region; 42, second region; 43, backing film; 44, backplate; 45, polarizer; 46, lower optically clear adhesive; 47, touch panel; 48, upper optically clear adhesive; 50, glass cover plate; 60, pressure sensitive adhesive layer.

### DETAILED DESCRIPTION

To describe the objective, the technical solutions and the advantages of the present disclosure more clearly, the technical solutions in embodiments of the present disclosure are described clearly and thoroughly in conjunction with drawings in the embodiments of the present disclosure. Apparently, the described embodiments are merely a part of rather than all the embodiments of the present disclosure. All other embodiments obtained by a person ordinary skilled in the art based on the embodiments of the present disclosure without any creative efforts fall within the scope of the present disclosure.

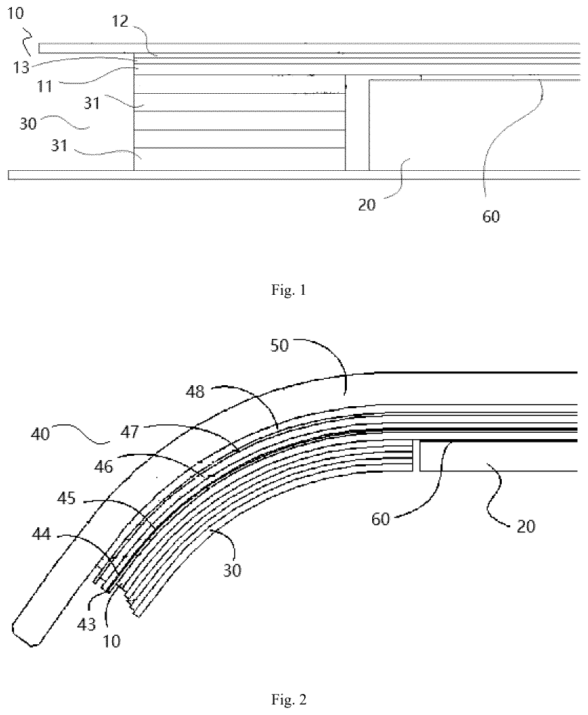

As shown in FIGS. 1 to 3, the heat dissipation structure of the first embodiment includes: a first heat dissipation layer 10, a support layer 20 and a second heat dissipation layer 30. The support layer 20 and the second heat dissipation layer 30 are arranged on the same side of the first heat dissipation layer 10, and the orthographic projection of the support layer 20 onto the first heat dissipation layer 10 and the second heat dissipation layer 30 onto the first heat dissipation layer 10 do not overlap.

With the technical solution of the present disclosure, heat dissipation are generally effected through three modes: heat radiation, heat conduction and heat convection. The support layer 20 and the second heat dissipation layer 30 are provided on the same side of the first heat dissipation layer 10, so that heat dissipation tends to be consistent in the region where the support layer 20 is provided and the region where the second heat dissipation layer 30 is provided, and a large temperature difference between the region of the first heat dissipation layer 10 where the support layer 20 is located and the region of the first heat dissipation layer 10 where the second heat dissipation layer 30 is located is avoided. In addition, the orthographic projection of the support layer 20 onto the first heat dissipation layer 10 and the orthographic projection of the second heat dissipation layer 30 onto the first heat dissipation layer 10 do not overlap, and such a structure makes the support layer 20 and the second heat dissipation layer 30 less likely to interfere with each other when the heat dissipation structure is bent. The technical solution of the embodiment effectively solves the problem of uneven heat dissipation of the heat dissipation structure in the related art.

As shown in FIGS. 1 and 2, in the technical solution of the embodiment, there is a gap between the support layer 20 and the second heat dissipation layer 30, and the gap is between 0.1 mm and 0.45 mm. The above-mentioned gap ensures that when the support layer 20 and the second heat dissipation layer 30 convert from a flat state into a bent state, the second heat dissipation layer 30 is deformed while the support layer 20 and the second heat dissipation layer 30 do not interfere with each other. In addition, the above-mentioned range of the gap distance is also due to the limitation of the manufacturing process and the state of art.

As shown in FIGS. 1 and 2, in the technical solution of the embodiment, the thickness of the support layer 20 and the thickness of the second heat dissipation layer 30 are the same. This advantageously eliminates mold mark defect and facilitates subsequent processing. For example, when a force is applied to the heat dissipation structure to bend the heat dissipation structure, since the thickness of the support layer 20 is the same as the thickness of the second heat dissipation layer 30, the support layer 20 and the second heat dissipation layer 30 may be easily attached as a whole to the bearing film.

It can be seen from the above that such processing is relatively convenient; for example, the attaching is relatively easy when deforming the second region 42 by bending in a later stage, because it is not necessary to consider the effect caused by the height difference between the second heat dissipation layer 30 and the support layer 20; for another example, in a later process, the arrangement of a support structure behind the support layer 20 and the second heat dissipation layer 30 is relatively convenient, and the processing cost is relatively low. It should be noted that the thickness of the support layer 20 and the thickness of the second heat dissipation layer 30 being the same can also be construed as the thickness of the second heat dissipation layer 30 and the thickness of the support layer 20 being approximately the same. The foregoing description ignores the thickness of a pressure sensitive adhesive layer 60, or a pressure sensitive adhesive layer 60 of the same thickness is also coated on the second heat dissipation layer 30.

In the first embodiment, as shown in FIGS. 1 and 2, the second heat dissipation layer 30 includes a plurality of heat dissipation sub-layers 31, and the heat dissipation sub-layers 31 are arranged on top of each other in a stack. On one hand, the arrangement of the plurality of heat dissipation sub-layers 31 satisfies the need for heat dissipation, and the arrangement is flexible; for example, different metals can be utilized, the thickness of each heat dissipation sub-layer 31 can be set individually, and the thicknesses of adjacent heat dissipation sub-layers 31 can be the same or different, so that the heat dissipation layer can cause the temperature of the second region 42 to be more consistent with the temperature of the first region 41. On the other hand, the structure of the plurality of heat dissipation sub-layers 31 ensures that the heat dissipation layer is easily deformed when bent, the exerted force can be small, and the heat dissipation layer is less likely to be damaged. The heat dissipation sub-layers 31 may be attached to each other by using an adhesive glue or a thermal adhesive.

It is noted that the heat dissipation sub-layers 31 may be made of the same material, or may be made of different materials. Each of the heat dissipation sub-layers 31 may be a copper plate, or an aluminum plate, or a graphite layer, or a graphene layer, etc., or may be formed by a layer of copper plate and a layer of aluminum plate, or may be formed by plural layers of copper plates sandwiching an aluminum plate, or the like. Regardless of the combination, the heat dissipation sub-layers 31 cause the temperature of the first region 41 and the temperature of the second region 42 to be the same eventually.

As shown in FIGS. 1 to 3, in the technical solution of first embodiment, the first heat dissipation layer 10 includes a copper foil layer 11 and a meshed adhesive layer 12, the second heat dissipation layer 30 and the support layer 20 are provided on the same side of the copper foil layer 11, and the meshed adhesive layer 12 is located on the side of the copper foil layer 11 facing away from the support layer 20. The above-mentioned structure, on one hand, ensures the uniformity of heat dissipation, and on the other hand, ensures that the heat dissipation structure is adequately attached to the display panel 40.

It is noted that the first heat dissipation layer 10 further includes a foam layer 13, and the foam layer 13 is located between the copper foil layer 11 and the meshed adhesive layer 12. The above-mentioned structure ensures that the heat dissipation layer can be better attached. Specifically, the bottom layer of the display panel 40 adopts a structure of EMBO (meshed adhesive)+Foam+Cu foil (copper foil), which can effectively prevent the generation of air bubbles and mold mark defect during attachment.

As shown in FIGS. 1 and 2, in the technical solution of the embodiment, the second heat dissipation layer 30 and the support layer 20 are both plate-shaped structures. It should be noted that the heat dissipation layer of the above-mentioned structure has a larger contact area with the display panel 40 to facilitate heat conduction and heat radiation, and such a structure enables a faster heat transfer rate.

It is noted that the support layer 20 is made of a metal material, which may be an aluminum material or an Al—Ti alloy or SUS stainless steel, etc. In the technical solution of the embodiment, an aluminum alloy material is used, and an aluminum plate is attached to a non-display surface (the surface of the display panel 40 facing away from the light-emitting side) of the first region 41, so that the support layer 20 not only plays the role of a support component but also plays the role of a heat dissipation component. Likewise, the heat dissipation layer is also made of a metal material. The metal material is better in terms of both heat conduction and heat radiation. It should be noted that the heat dissipation layer, besides the purpose of heat dissipation, may also support the second region 42 against deformation.

A display module is fabricated by attaching the heat dissipation structure of the first embodiment to the display panel 40. The display module includes: a heat dissipation structure and a display panel 40. The heat dissipation structure is the heat dissipation structure described above. The display panel 40 includes a first region 41 and a second region 42 connected to each other, the second region 42 can be bent and deformed, the heat dissipation structure is attached to the display panel 40, the first heat dissipation layer 10 is located in the first region 41 and the second region 42, the support layer 20 is located in the first region 41, and the second heat dissipation layer 30 is located in the second region 42.

The first region 41 of the display panel 40 is supported by the support layer 20, and the support layer 20, while supporting the first region 41, dissipates heat from the first region 41 by means of heat radiation and heat conduction. The second region 42 of the display panel 40 dissipates heat through the second heat dissipation layer 30, in this way, the second region 42 also dissipates heat by means of heat radiation and heat conduction. The above-mentioned structure enables both the first region 41 and the second region 42 to dissipate heat, so that the temperature of the first region 41 and the temperature of the second region 42 tend to be uniform, thereby effectively addressing the problem in the related art that the temperature of the first region 41 and the temperature of the second region 42 differ greatly. The display module having such a structure effectively solves the problem of uneven heat dissipation of the display module in the related art.

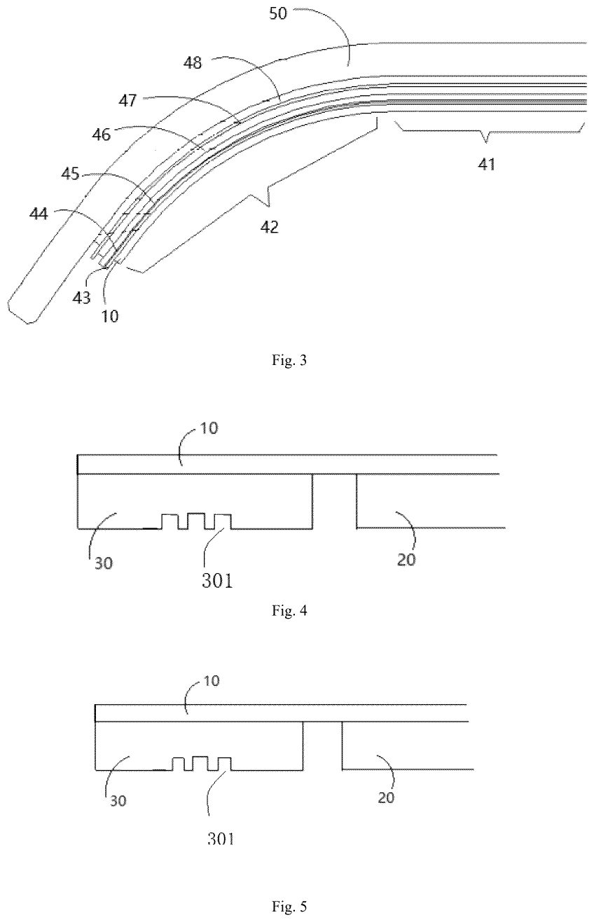

It should be noted that the above-mentioned display module is a display module applied to a vehicle, the first region 41 is a planar region, the second region 42 is a bent region, and it can be seen from FIG. 3 that the second region 42 is located at an edge of the first region 41, and two second regions 42 are located at two opposite edges of the first region 41, respectively. As another implementation, each peripheral edge of the first regions 41 is provided with the second region 42, and the second heat dissipation layers 30 are provided in correspondence with the second regions 42. The display panel 40 is composed of multiple layers, and includes a backing film 43, a backplate 44, a polarizer 45, a lower optically clear adhesive 46, a touch panel 47, an upper optically clear adhesive 48 and the like which are arranged sequentially in a direction away from the support layer 20; the side of the display panel 40 facing away from the support layer 20 is provided with a glass cover plate 50.

As shown in FIGS. 1 and 2, in the technical solution of the embodiment, the side edge of the second heat dissipation layer 30 facing away from the support layer 20 is located closer to the support layer 20 than the side edge of the second region 42 facing away from the first region 41. Namely, the outer edge of the second heat dissipation layer 30 is staggered inwards by a certain distance, so as to prevent adhesive leakage, in other words, the adhesive on the second heat dissipation layer 30 is not liable to interfere with the display panel 40. Specifically, the distance by which the outer edge is staggered inwards is 0.3 mm in the embodiment, which prevents adhesive leakage and does not affect the uniformity of heat dissipation. When the second region 42 of the display panel 40 is bent, the edges of the plurality of heat dissipation sub-layers 31 are staggered. As another implementation, when the display module is in a flat state, a side of the second heat dissipation layer 30 facing away from the support layer 20 is flush with a side of the second region 42 facing away from the first region 41 in a plane perpendicular to the display module. Such a structure is advantageous in heat dissipation, thereby further reducing the probability that a large temperature difference occurs in the display panel 40, that is, temperatures at various positions of the second region 42 of the display panel 40 tend to be uniform, and the temperature of the first region 41 of the display panel 40 and the temperature of the second region 42 of the display panel 40 also tend to be uniform, so that the problem of yellowing of the display panel 40 due to uneven temperature does not easily occur.

As shown in FIGS. 1 and 2, in the technical solution of the embodiment, the second heat dissipation layer 30 has a predetermined distance from the bending start point of the second region 42. The predetermined distance can satisfy the processing requirements of the second heat dissipation layer 30 on one hand, and on the other hand, the above-mentioned structure can also ensure that the interference between the second heat dissipation layer 30 and the support layer 20 does not easily occur when the display panel 40 is bent and deformed.

The predetermined distance is between 0.08 mm and 0.35 mm depending on the manufacturing process. Specifically, the predetermined distance is 0.3 mm, so that in case that the second heat dissipation layer 30 adopts the multi-layer structure, when the display panel 40 is in a flat state as a whole, a side of the second heat dissipation layer 30 that is close to the support layer 20 is flush in a plane perpendicular to the display panel 40, in other words, the side edge of the second heat dissipation layer 30 close to the support layer 20 is at the same distance to the side edge of the support layer 20 close to the second heat dissipation layer 30. When the second region 42 of the display panel 40 is in a bent state, side edges of the multiple heat dissipation sub-layers 31 are staggered, in other words, the side edges of the multiple heat dissipation sub-layers 31 on a side close to the support layer 20 are not in said plane.

In the technical solution of the first embodiment, there are two second region 42, there are two second heat dissipation layers 30, the two second regions 42 are arranged on two opposite sides of the first region 41, respectively, and the two second heat dissipation layers 30 are arranged in one-to-one correspondence with the two second regions 42.

In the technical solution of the first embodiment, the display panel 40 is a flexible display panel, and the light-emitting layer may be an organic light-emitting diode (OLED). OLED is a current-type organic light-emitting device, which emits light through the injection and recombination of charge carriers, and the emission intensity is directly proportional to the injected current. When the OLED is under the influence of an electric field, holes generated at the anode and electrons generated at the cathode move to inject into a hole transport layer and an electron transport layer, respectively, and migrate to the light-emitting layer. When the holes and the electrons meet at the light-emitting layer, energetic excitons are generated, which excite the light-emitting molecules to eventually produce visible light.

As shown in FIG. 4, the heat dissipation structure of the second embodiment differs from the heat dissipation structure of the first embodiment in that the second heat dissipation layer 30 has a plate-like structure, the side of the plate-like structure that is facing away from the display panel 40 is provided with a groove, and the longitudinal extension direction of the groove is consistent with the extension direction of an axis around which the second region 42 bends. The provision of grooves 301 in the second heat dissipation layer 30 improves the heat exchange efficiency because the structure in which the heat dissipation layer is provided with the grooves 301 increases the flat surface perpendicular to the surface of the display panel 40, thus increasing the heat dissipation area. In addition, the provision of the grooves 301 in the second heat dissipation layer 30 may also reduce the force applied when bending the second region 42.

In the technical solution of the second embodiment, the first region 41 of the display panel 40 is supported by the support layer 20, the support layer 20 dissipates heat from the first region 41 by means of heat radiation and heat conduction while supporting the first region 41, and the second region 42 of the display panel 40 dissipates heat through the second heat dissipation layer 30, so that the second region 42 also dissipates heat by means of heat radiation and heat conduction. The above-mentioned structure enables both the first region 41 and the second region 42 to dissipate heat, so that the temperature of the first region 41 and the temperature of the second region 42 tend to be uniform, thereby effectively addressing the problem in the related art that the temperature of the first region 41 and the temperature of the second region 42 differ greatly.

In the technical solution of the second embodiment, a plurality of grooves 301 are provided, and the plurality of grooves 301 are provided in parallel. Such a structure further increases the heat dissipation efficiency of the second region 42. In addition, when the second heat dissipation layer 30 is bent, the force exerted on the second heat dissipation layer 30 is more uniform. It should be noted that in the technical solution of the embodiment, grooves 301 are of the same structure, the grooves 301 have a width between 0.03 mm and 1 mm, the length of each groove 301 is the same as the length of the axis around which the second region 42 bends, the grooves 301 have a depth between 0.01 mm and 0.8 mm, and the grooves 301 have the same depth. In other implementations, the grooves 301 may have different depths.

In the technical solution of the second embodiment, the second heat dissipation layer 30 has a plate-shaped structure, the heat dissipation layer is a monolithic copper plate, a side of the copper plate facing away from the display panel 40 is provided with grooves 301, and the grooves 301 extend in the direction of the axis around which the copper plate bends. A side of the second heat dissipation layer 30 close to the support layer 20 is at a predetermined distance to the bending start point of the second region 42. The predetermined distance can satisfy the processing requirements of the second heat dissipation layer 30. The predetermined distance of the embodiment is smaller than that of the first embodiment, and the predetermined distance can be 0.1 mm. When the display module is in a flat state, the side edge of the second heat dissipation layer 30 facing away from the support layer 20 is closer to the support layer 20 than the side edge of the second region 42 facing away from the first region 41. In other words, the outer edge of the second heat dissipation layer 30 is staggered inwards by a certain distance, so as to prevent adhesive leakage, that is, the adhesive on the second heat dissipation layer 30 is not liable to interfere with the display panel 40.

In the technical solution of this embodiment, as another possible implementation, the second heat dissipation layer 30 may be a monolithic aluminum plate. The use of the aluminum plate can reduce costs. The specific choice of used material depends on the magnitude of the temperature difference between the first region 41 and the second region 42.

It can be seen from the above that the structure of the technical solution of the second embodiment is that the display module is divided into a flat region and two bent regions at opposite sides of the flat region, and the edges of the two bent regions are bent in a direction toward a non-display area. A support layer made of an aluminum alloy is attached to a non-display surface of the flat region, and the distance between the edge of each heat dissipation sub-layer 31 and the edge of the support layer 20 is 0.1 mm.

As shown in FIG. 5, the technical solution of the third embodiment differs from the technical solution of the second embodiment in that the plurality of grooves 301 in the third embodiment are symmetrically arranged, the width of the middle groove 301 is largest, and the widths of grooves 301 on both sides of the middle groove 301 gradually decrease in a sideway direction. This better conforms to the usage scenario of the second region 42. Such an arrangement is more accurate in that the width of the groove 301 is larger at the position where the second region 42 experiences greater variation, and the widths of the grooves 301 on both sides gradually decrease.

The third embodiment may be the same as the second embodiment in terms of other structures, and detailed description thereof will not be repeated.

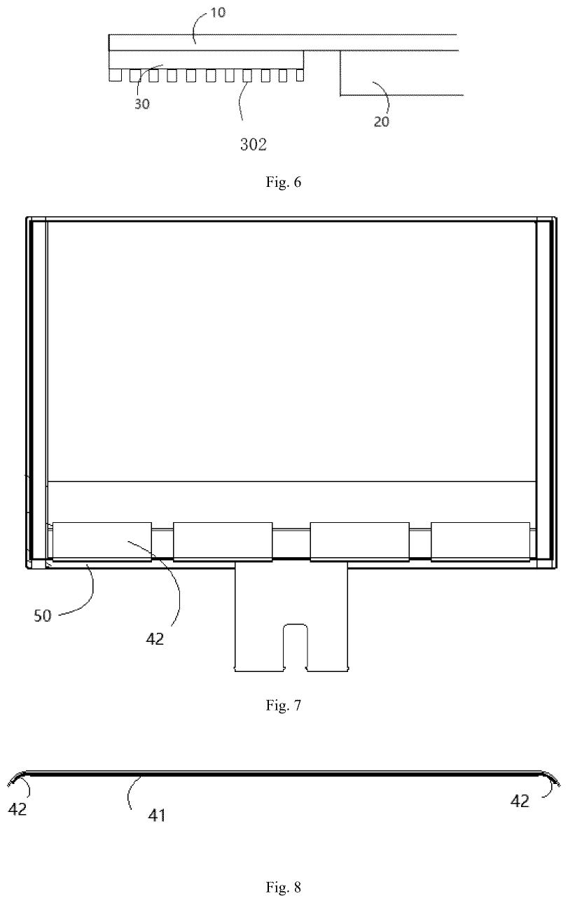

As shown in FIG. 6, in the technical solution of the fourth embodiment, the second heat dissipation layer 30 includes a metal plate body and a plurality of protrusions 302 provided on the same surface of the metal plate body. A side of the metal plate body facing away from the plurality of protrusions 302 is attached to the display panel 40. This further increases the heat dissipation area of the second heat dissipation layer 30.

In the technical solution of the fourth embodiment, the plurality of protrusions 302 are arranged in an array, and this structure can reduce the force required to bend the second region 42. It should be noted that if the axis of bending is considered as a row direction, rows in the array are parallel to each other along the axis of bending. In this way, when the second region 42 is bent, the reactive force exerted by the second heat dissipation layer 30 is relatively small.

As shown in FIGS. 7 and 8, the present disclosure also provides an electronic device. The electronic device includes a display module, and the display module is the above-mentioned display module. The display screen of such electronic devices has long usage period. An embodiment of the electronic device may be a vehicle-mounted display screen.

The present disclosure also provides a processing method for a display module. The display module is the display module described above. The processing method includes the following steps: providing a second heat dissipation layer 30 in a second region 42 of the display panel 40; attaching a bearing film to a side of the second heat dissipation layer 30 facing away from the display panel 40; and bending the display panel 40 having the second heat dissipation layer 30 by applying a force to the bearing film. The processing method for a display module sets a bearing film on the display panel 40 provided with the second heat dissipation layer 30, and then applies a force to the bearing film, and the bearing film drives the display module so that the second region 42 is bent to have a predetermined bending curvature. This method ensures that the second region 42 is subjected to relatively uniform forces during bending deformation. More importantly, the display module is relatively delicate and the forces applied in this method would not damage the display module. When the vehicle-mounted display module is bent, the display module is bent into a predetermined bent form as needed.

Before providing the second heat dissipation layer 30 in the second region 42 of the display panel 40, the processing method for a display module of the present disclosure further includes the following sequential steps: the attachment of a polarizer→the cutting of the pad area→the bonding of the flip chip film→the bonding of the PCB→the external shape cutting→the attachment of the lower optically clear adhesive→the attachment of the cover plate, the upper optically clear adhesive and the touch control screen together onto the lower layer optical transparent adhesive. On one hand, processing the display panel 40 in such a processing method ensures that the processing accuracy of the display module is adequate, and on the other hand, such a processing method avoids repeating the processing steps and has the beneficial effect of saving manpower and material resources.

After bending the display panel 40 having the second heat dissipation layer 30, the processing method of the display module of the present disclosure further includes: attaching the bent display panel 40 having the second heat dissipation layer 30 onto a flexible printed circuit board.

It is noted that relational terms such as “first”, “second”, and the like are used solely to distinguish one entity or operation from another entity or operation without necessarily requiring or implying that any such relationship or order between such entities or operations actually exists. Furthermore, the terms “include”, “comprise”, or any other variation thereof, are intended to cover a non-exclusive inclusion, such that a process, method, article, or device that includes a list of elements does not include only those elements but may include other elements not expressly listed or inherent in such process, method, article, or device. An element defined by the expression “include” does not preclude the existence of additional identical elements in the process, method, article, or device that includes the element, if there is no more constraints.

Specific implementations of the present disclosure are described above, to enable a person skilled in the art to understand or implement the present disclosure. Various modifications to these embodiments will be readily apparent to those skilled in the art, and the general principles defined herein may be implemented in other embodiments without departing from the spirit or scope of the disclosure. Thus, the present disclosure is not intended to be limited to the embodiments shown herein, but is to be accorded the widest scope consistent with the principles and novel features disclosed herein.

1. A heat dissipation structure, comprising: a first heat dissipation layer, a support layer, and a second heat dissipation layer, wherein
the support layer and the second heat dissipation layer are arranged on a same side of the first heat dissipation layer, and an orthographic projection of the support layer onto the first heat dissipation layer and an orthographic projection of the second heat dissipation layer onto the first heat dissipation layer do not overlap.

2. The heat dissipation structure according to claim 1, wherein the support layer and the second heat dissipation layer have a gap therebetween, wherein the gap is between 0.1 mm and 0.45 mm.

3. The heat dissipation structure according to claim 1, wherein a thickness of the support layer is the same as a thickness of the second heat dissipation layer.

4. The heat dissipation structure according to claim 1, wherein the second heat dissipation layer comprises a plurality of heat dissipation sub-layers, and the heat dissipation sub-layers are arranged in a stack.

5. The heat dissipation structure according to claim 4, wherein the heat dissipation sub-layers are made of a same material, or the plurality of heat dissipation sub-layers are made of different materials.

6. The heat dissipation structure according to claim 1, wherein the first heat dissipation layer comprises a copper foil layer and a meshed adhesive layer, the second heat dissipation layer and the support layer are arranged on a same side of the copper foil layer, and the meshed adhesive layer is located on a side of the copper foil layer facing away from the support layer.

7. The heat dissipation structure according to claim 6, wherein the first heat dissipation layer further comprises a foam layer, and the foam layer is located between the copper foil layer and the meshed adhesive layer.

8. A display module, comprising:
a heat dissipation structure comprising: a first heat dissipation layer, a support layer, and a second heat dissipation layer, wherein the support layer and the second heat dissipation layer are arranged on a same side of the first heat dissipation layer, and an orthographic projection of the support layer onto the first heat dissipation layer and an orthographic projection of the second heat dissipation layer onto the first heat dissipation layer do not overlap; and
a display panel, comprising a first region and a second region connected to each other, wherein the second region is deformable by bending, the heat dissipation structure is attached to the display panel, the first heat dissipation layer is located in the first region and the second region, the support layer is located in the first region, and the second heat dissipation layer is located in the second region.

9. The display module according to claim 8, wherein a side of the second heat dissipation layer facing away from the support layer is flush with a side of the second region facing away from the first region in a plane perpendicular to the display module; or a side edge of the second heat dissipation layer facing away from the support layer is closer to the support layer than a side edge of the second region facing away from the first region.

10. The display module according to claim 8, wherein the second heat dissipation layer has a predetermined distance from a bending start point of the second region.

11. An electronic device, comprising the display module according to claim 8.

12. A processing method for a display module, wherein the display module is the display module according to claim 8, and the processing method comprises the following steps:
providing a second heat dissipation layer in the second region of the display panel;
attaching a bearing film on a side of the second heat dissipation layer facing away from the display panel; and
bending the display panel having the second heat dissipation layer by applying a force to the bearing film.

13. The processing method according to claim 12, wherein after bending the display panel having the second heat dissipation layer, the method further comprises: attaching the bent display panel having the second heat dissipation layer onto a flexible printed circuit board.

14. A display module, comprising:
a heat dissipation structure comprising: a first heat dissipation layer, a support layer, and a second heat dissipation layer, wherein the support layer and the second heat dissipation layer are arranged on a same side of the first heat dissipation layer, and an orthographic projection of the support layer onto the first heat dissipation layer and an orthographic projection of the second heat dissipation layer onto the first heat dissipation layer do not overlap, wherein the support layer and the second heat dissipation layer have a gap therebetween, wherein the gap is between 0.1 mm and 0.45 mm; and
a display panel, comprising a first region and a second region connected to each other, wherein the second region is deformable by bending, the heat dissipation structure is attached to the display panel, the first heat dissipation layer is located in the first region and the second region, the support layer is located in the first region, and the second heat dissipation layer is located in the second region.

15. A display module, comprising:
the heat dissipation structure according to claim 3; and
a display panel (40), comprising a first region (41) and a second region (42) connected to each other, wherein the second region (42) is deformable by bending, the heat dissipation structure is attached to the display panel (40), the first heat dissipation layer (10) is located in the first region (41) and the second region (42), the support layer (20) is located in the first region (41), and the second heat dissipation layer (30) is located in the second region (42).

16. A display module, comprising:
the heat dissipation structure according to claim 4; and
a display panel (40), comprising a first region (41) and a second region (42) connected to each other, wherein the second region (42) is deformable by bending, the heat dissipation structure is attached to the display panel (40), the first heat dissipation layer (10) is located in the first region (41) and the second region (42), the support layer (20) is located in the first region (41), and the second heat dissipation layer (30) is located in the second region (42).

17. A display module, comprising:
the heat dissipation structure according to claim 5; and
a display panel (40), comprising a first region (41) and a second region (42) connected to each other, wherein the second region (42) is deformable by bending, the heat dissipation structure is attached to the display panel (40), the first heat dissipation layer (10) is located in the first region (41) and the second region (42), the support layer (20) is located in the first region (41), and the second heat dissipation layer (30) is located in the second region (42).

18. A display module, comprising:
the heat dissipation structure according to claim 6; and
a display panel (40), comprising a first region (41) and a second region (42) connected to each other, wherein the second region (42) is deformable by bending, the heat dissipation structure is attached to the display panel (40), the first heat dissipation layer (10) is located in the first region (41) and the second region (42), the support layer (20) is located in the first region (41), and the second heat dissipation layer (30) is located in the second region (42).

19. A display module, comprising:
the heat dissipation structure according to claim 7; and
a display panel (40), comprising a first region (41) and a second region (42) connected to each other, wherein the second region (42) is deformable by bending, the heat dissipation structure is attached to the display panel (40), the first heat dissipation layer (10) is located in the first region (41) and the second region (42), the support layer (20) is located in the first region (41), and the second heat dissipation layer (30) is located in the second region (42).

20. An electronic device, comprising the display module according to claim 9.
